(19) United States
(12) Patent Application Publication
(10) Pub. No.: US 2024/0036460 A1
(43) Pub. Date: Feb. 1, 2024

(54) PROTECTIVE MEMBRANE FOR PHOTO LITHOGRAPHY, PELLICLE INCLUDING THE SAME, AND METHOD OF FORMING THE SAME

(71) Applicant: Samsung Electronics Co., Ltd., Suwon-si (KR)

(72) Inventors: MUN JA KIM, Suwon-si (KR); Seung Hyun Lee, Seongnam-si (KR); Jae Sun Jung, Seongnam-si (KR); Byungchul Yoo, Suwon-si (KR); Byunghoon Lee, Suwon-si (KR); Changyoung Jeong, Suwon-si (KR); Deok Hyun Kim, Seongnam-si (KR); Deok Hyun Cho, Seongnam-si (KR)

(73) Assignee: Soulbrain Co., Ltd., Seongnam-Si (KR)

(21) Appl. No.: 18/186,994

(22) Filed: Mar. 21, 2023

(30) Foreign Application Priority Data
Jul. 26, 2022 (KR) 10-2022-0092156

(51) Int. Cl. G03F 1/62

(52) U.S. Cl. CPC G03F 1/62

(57) ABSTRACT

Provided herein are protective membranes for lithography that include a core layer including carbon, an interface layer on the core layer, and a protective layer on the interface layer. The interface layer includes a reactive group bonded to a carbon atom of the core layer and the reactive group includes oxygen or nitrogen. The protective layer includes an element “M”, and the element “M” is bonded to the oxygen or nitrogen of the reactive group.

### CROSS-REFERENCE TO RELATED APPLICATIONS

This patent application claims priority under 35 U.S.C. § 119 to Korean Patent Application No. 10-2022-0092156, filed on Jul. 26, 2022, in the Korean Intellectual Property Office, the entire contents of which are hereby incorporated by reference.

### FIELD

The inventive concept relates to a protective membrane for photolithography processes used in manufacturing semiconductor devices, pellicles including the same, and methods of forming the same.

### BACKGROUND

In semiconductor device manufacturing processes, photolithography may be used to form a circuit pattern on a substrate. In some cases, a protective membrane that protects components in the apparatus performing the photolithography process from external contaminants (e.g., dust or resist materials) may be required. As the critical dimension of a semiconductor device decreases, the wavelength of light used in photolithography processes may be decreased, and research on protective membranes suitable for photolithography processes using light having relatively short wavelengths is being conducted.

For example, in some photolithography processes, a photomask is used to transfer a desired pattern onto a substrate. The protective membrane may be used in a pellicle provided on the photomask to protect the photomask from external contaminants (e.g., dust or resist materials). The protective membrane used for the pellicle should have relatively high transmittance for the light used in the photolithography process, and the pellicle should also satisfy other requirements such as sufficient heat dissipation, strength, durability, and stability.

### SUMMARY

An object of the inventive concept is to provide a protective membrane for photolithography that has desirable heat dissipation and desirable chemical and mechanical durability, a pellicle including the same, and a manufacturing method thereof.

The problem to be solved by the inventive concept is not limited to the problems mentioned above, and other problems not mentioned will be clearly understood by those skilled in the art from the following description.

A protective membrane for photolithography according to some embodiments of the inventive concept may include a core layer including carbon, an interface layer on the core layer, and a protective layer on the interface layer. The interface layer may include a reactive group bonded to a carbon atom of the core layer and the reactive group may include an oxygen atom or a nitrogen atom. The protective layer may include an element “M” and the element “M” may be bonded to the oxygen atom or the nitrogen atom of the reactive group.

A pellicle for a photo mask according to some embodiments of the inventive concept may include a pellicle membrane and a pellicle frame supporting the pellicle membrane. The pellicle membrane may include a core layer including carbon, an interface layer on the core layer, and a protective layer on the interface layer. The interface layer may include a reactive group bonded to a carbon atom of the core layer and the reactive group may include an oxygen atom or nitrogen atom. The protective layer may also include an element “M” and the element “M” may be bonded to the oxygen atom or the nitrogen atom of the reactive group.

A method of forming a protective membrane for photography according to some embodiments of the inventive concept may include providing a core layer including carbon, performing a plasma treatment process on the core layer to form an interface layer, and performing an atomic layer deposition process on the interface layer to form a protective layer. The forming of the interface layer may include forming a reactive group including an oxygen atom or a nitrogen atom bonded to a carbon atom of the core layer by the performing of the plasma process. The protective layer may include an element “M” and the element “M” may be bonded to the oxygen atom or the nitrogen atom of the reactive group.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view of a protective membrane for photolithography according to some embodiments of the inventive concept.

FIGS. 2A to 2D are enlarged views of portion “A” of FIG. 1.

FIG. 3 is a cross-sectional view of a protective membrane for photolithography according to some embodiments of the inventive concept.

FIG. 4 is a cross-sectional view of a protective membrane for photolithography according to some embodiments of the inventive concept.

FIGS. 5A and 5B are enlarged views of portion “B” of FIG. 4.

FIG. 6 is a cross-sectional view illustrating a method of manufacturing a protective membrane for photolithography according to some embodiments of the inventive concept.

FIGS. 7A and 7B are enlarged views of portion “C” of FIG. 6.

FIG. 8 is a cross-sectional view illustrating a method of manufacturing a protective membrane for photolithography according to some embodiments of the inventive concept.

FIGS. 9A and 9B are enlarged views of portion “D” of FIG. 8.

FIG. 10 provides SEM images of protective membranes for photolithography according to the Comparative Examples.

FIG. 11 provides SEM images of protective membranes for photolithography according to Examples of the inventive concept.

FIGS. 12 and 13 provides TEM images illustrating a cross-section of a protective membrane for photolithography according to embodiments of the inventive concept.

FIG. 14 is a graph quantitatively illustrating a Ti content with respect to a thickness of a TiN protective layer in a protective membrane for photolithography according to embodiments of the inventive concept.

FIG. 15 is a graph illustrating growth by atomic layer deposition over time for protective membranes for photolithography according to embodiments of the inventive concept and Comparative Example 1.

FIG. 16 is a graph illustrating a Raman spectrum of a core layer including multilayer graphene before and after being exposed to hydrogen plasma.

FIGS. 17 to 19 are graphs illustrating Raman spectra of protective membranes formed according to Examples 1, 2, and 3 before and after being exposed to hydrogen plasma, respectively.

FIG. 20 is a graph illustrating the change in the ratio of signal sensitivity obtained from the Raman spectra in FIGS. 16 to 19.

FIG. 21 is a graph illustrating the change in the ratio of signal sensitivity for protective membranes formed according to Examples 4 to 6 before and after being exposed to hydrogen plasma.

FIGS. 22 to 24 are cross-sectional views of a pellicle including a protective membrane for photolithography according to embodiments of the inventive concept.

FIG. 25 is a cross-sectional view of a reticle including a pellicle for a photo mask according to embodiments of the inventive concept.

FIG. 26 is a conceptual diagram of an exposure apparatus for lithography using a reticle including a pellicle according to embodiments of the inventive concept.

FIG. 27 is a conceptual diagram of an exposure apparatus for lithography using a reticle including a pellicle according to embodiments of the inventive concept.

### DETAILED DESCRIPTION

Hereinafter, embodiments of the inventive concept will be described in detail with reference to the accompanying drawings.

The terms “about,” when used herein in reference to a value, are used interchangeably and refer to a value that is similar to the referenced value. In general, those skilled in the art, familiar with the context, will appreciate the relevant degree of variation encompassed by “about” in that context. For example, in some embodiments, the terms “about” may encompass a range of values that fall within 10%, 9%, 8%, 7%, 6%, 5%, 4%, 3%, 2%, 1%, or less of the referred value.

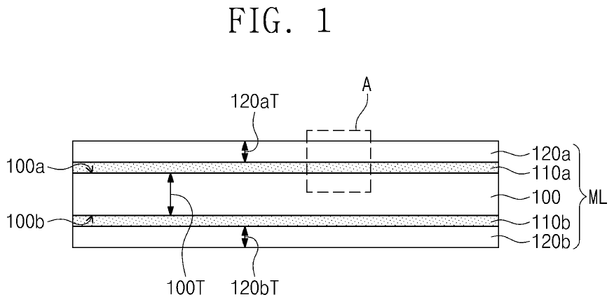

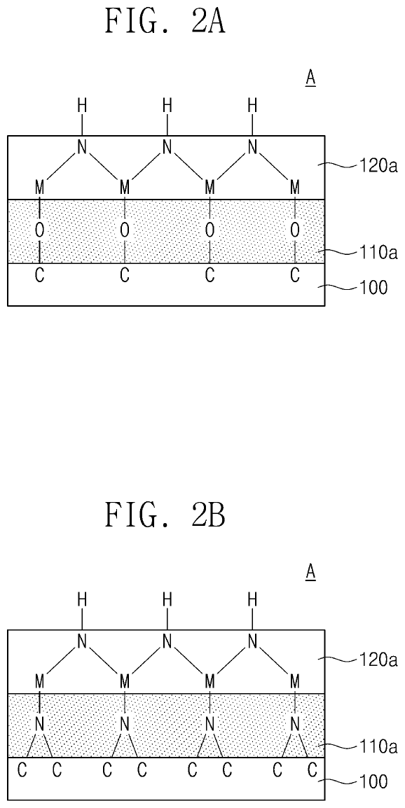

FIG. 1 is a cross-sectional view of a protective membrane for photolithography according to some embodiments of the inventive concept. FIGS. 2A to 2D are enlarged views of portion “A” of FIG. 1.

Referring to FIG. 1, a protective membrane ML for photolithography may include a core layer 100, interface layers 110a and 110b on the core layer 100, and protective layers 120a and 120b on the interface layers 110a and 110,b.

In some embodiments, the core layer 100 may include carbon (e.g., a carbon-based material such as a carbon nanomaterial). The core layer 100 may include, for example, at least one of single-layer graphene, multi-layer graphene, carbon nanotubes (CNT), fullerene, nanographite, and graphite. In some embodiments, the core layer may be a carbon-based material that is substantially or entirely formed of carbon (e.g., 80 at % or more, 85 at % or more, 90 at % or more, 95 at % or more, 99 at % or more, or 100 at % carbon).

The interface layers 110a and 110b may include a reactive group that is bonded to a carbon (C) atom of the core layer 100, and in some embodiments, the reactive group may include an oxygen (O) atom or nitrogen (N) atom. The term “bonded” means that the atoms are connected or combined, for example, with a covalent or ionic bond. The term “reactive group” indicates that the group bonds with the core layer and/or the protective layer in the protective membrane. The reactive group may be a single atom (e.g., a single nitrogen or oxygen atom) or may include additional atoms. In some embodiments, the reactive group may include, for example, at least one of a carbonyl (═O), an ether (—O—), a hydroxyl (—OH), an imine or tertiary amine (e.g., C═N— or C₂N—), an imine or secondary amine (e.g., C═NH or C₂NH), and a primary amine (—NH₂). In some embodiments, the interface layers 110a and 110b may bond with the core layer to form at least one of a C═O bond (carbonyl), a C—O—C bond (ether), a C—OH bond (hydroxyl), a C₂N—C bond (tertiary amine), a C═N—C bond (imine), a C₂NH bond (secondary amine), a C═NH bond (imine), and a C—NH₂ bond (primary amine). These functional groups are provided to show particular bonding sequences and additional atoms or moieties may be present in the functional groups. For example, the interface layers 110a and 110b may be connected to the core layer 100 through at least one of a C═O bond, a C—O—C bond, a C—OH bond, a C₂N—C bond, a C═N—C bond, a C₂NH bond, a C═NH bond, and a C—NH₂ bond.

Referring to FIGS. 1 and 2A to 2D, the protective layers 120a and 120b may include an element “M”, and the element “M” may be bonded to the oxygen or nitrogen atom in the reactive group of the interface layers 110a and 110b. Accordingly, the interface layers 110a and 110b may bond to the core layer and the protective layer to form a C—O—M bond (e.g., carbon from the core layer, the oxygen from the interface layer and metal from the protective layer), a C₂N—M bond (e.g., carbons from the core layer, the nitrogen from the interface layer and metal from the protective layer), a C═N—M bond (e.g., carbon from the core layer, the nitrogen from the interface layer and metal from the protective layer), and a C—NH—M bond (e.g., carbon from the core layer, the nitrogen and hydrogen from the interface layer and metal from the protective layer).

For example, referring to FIG. 2A, the element “M” of the protective layers 120a and 120b (not shown) may be bonded to an oxygen atom of the reactive group in the interface layers 110a and 110b (not shown), which is bonded to a carbon atom in the core layer 100, thus, forming a C—O—M bond. As another example, referring to FIGS. 2B to 2D, the element “M” of the protective layers 120a and 120b (not shown) may be bonded to a nitrogen atom of the reactive group of the interface layers 110a and 110b (not shown), which is bonded to a carbon (C) in the core layer 100, thus forming at least one of a C₂N—M bond (FIG. 2B), a C═N—M bond (FIG. 2C), and a C—NH—M bond (FIG. 2D).

In some embodiments, the protective layer 120a and/or the protective layer 120b may include a nitride including the element “M”. In some embodiments, the element “M” may include at least one of Ti, B, Ta, Nb, V, Cu, Ga, Ge, Zr, Mo, In, Hf, and W. For example, in particular embodiments, the element “M” is Ti, and the protective layers 120a and 120b include TiN.

Referring back to FIG. 1, the core layer 100 may have a first surface 100a and a second surface 100b opposite to each other. According to some embodiments, a first interface layer 110a is on the first surface 100a of the core layer 100, and a second interface layer 110b is on the second surface 100b of the core layer 100. In some embodiments, a first protective layer 120a is on the first interface layer 110a and a second protective layer 120b is on the second interface layer 110b. As such, in some embodiments, the first interface layer 110a may be interposed between the core layer 100 and the first protective layer 120a, and the second interface layer 110b may be interposed between the core layer 100 and the second protective layer 120b.

The protective membrane may include a first reactive group in the first interface layer 110a and a second reactive group in the second interface layer 110b. The first reactive group may include at least one of a carbonyl (═O), an ether (—O—), a hydroxyl (—OH), an imine or tertiary amine (e.g., C═N— or C₂N—), an imine or secondary amine (e.g., C═NH or C₂NH), and a primary amine (—NH₂) and the second reactive group may include at least one of a carbonyl (═O), an ether (—O—), a hydroxyl (—OH), an imine or tertiary amine (e.g., C═N— or C₂N—), an imine or secondary amine (e.g., C═NH or C₂NH), and a primary amine (—NH₂). The second reactive group may be the same as or different from the first reactive group. Each of the first interface layer 110a and the second interface layer 110b may form a bond with the core layer to form at least one of a C═O bond, a C—O—C bond, a C—OH bond, a C₂N—C bond, a C═N—C bond, a C₂NH bond, and a C═NH bond, and a C—NH₂ bond.

Each of the first protective layer 120a and the second protective layer 120b may include the element “M”. The element “M” of the first protective layer 120a may be bonded to an oxygen atom or nitrogen atom of the first reactive group of the first interface layer 110a. Accordingly, the first interface layer 110a may bond with the core layer and the protective layer to form at least one of a C—O—M bond, a C₂N—M bond, a C═N—M bond, and a C—NH—M bond. The element “M” of the second protective layer 120b may form a bond with the oxygen atom or nitrogen atom of the second reactive group of the second interface layer 110b. Accordingly, the second interface layer 110b may bond with the core layer and the protective layer to form at least one of a C—O—M bond, a C₂N—M bond, a C═N—M bond, and a C—NH—M bond.

In some embodiments, each of the first protective layer 120a and the second protective layer 120b may include a nitride including the element “M”. The first protective layer 120a and the second protective layer 120b may include the same or different materials. For example, in particular embodiments, the first protective layer 120a and the second protective layer 120b may include the same material, for example, TiN.

The core layer 100 may have a thickness 100T in a direction perpendicular to the first surface 100a and the second surface 100b. In some embodiments, the thickness 100T of the core layer 100 may be in a range of about 0.1 nm to about 100 nm. The thickness 100T of the core layer 100 may be, for example, in a range of about 0.1 nm to about 50 nm, and as another example, in a range of about 1 nm to about 100 nm. The first protective layer 120a may have a first thickness 120aT in the direction perpendicular to the first surface 100a and the second surface 100b, and the second protective layer 120b may have a second thickness 120bT in the direction perpendicular to the first surface 100a and the second surface 100b. In some embodiments, each of the first thickness 120aT and the second thickness 120bT may be in a range of about 0.5 nm to about 10 nm. In some embodiments, a surface roughness of each of the first protective layer 120a and the second protective layer 120b may be, for example, in a range of about 20 nm to about 30 nm. The surface roughness is determined by a distance between peaks and valleys on a surface of each of the first protective layer 120a and the second protective layer 120b. The larger the distance, the rougher the surface.

In some embodiments, each of the first protective layer 120a and the second protective layer 120b may include TiN. In this case, in some embodiments, a Ti content in each of the first protective layer 120a and the second protective layer 120b may be in a range of about 5.0 atomic % to about 6.0 atomic %. Further, in some embodiments, a TiN density in each of the first protective layer 120a and the second protective layer 120b may be in a range of about 5.0 g/cm³ to about 5.22 g/cm³.

In some aspects of the invention, the protective membrane ML may be used in an extreme ultraviolet photolithography process. In some embodiments, an extreme ultraviolet transmittance of the protective membrane ML may be about 80% or more and 100% or less. In some embodiments, an extreme ultraviolet reflectance of the protective membrane ML may be 0% or more and about 0.04% or less. In particular embodiments, the protective membrane ML may be used or configured for use in or with at least one of an optical filter, a dynamic gas lock filter, protectors for optics, and a pellicle, which are may be part of an apparatus performing an extreme ultraviolet photolithography process.

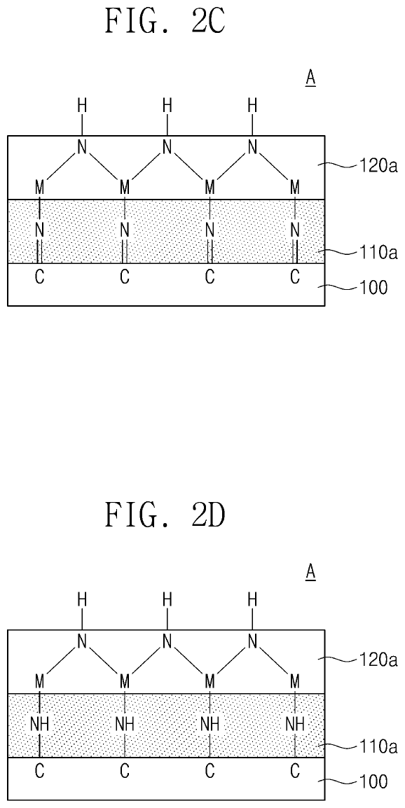

FIG. 3 is a cross-sectional view of a protective membrane for photolithography according to some embodiments of the inventive concept. For simplicity of explanation, differences from the protective membrane described with reference to FIGS. 1 and 2A to 2D will be primarily described.

Referring to FIG. 3, a protective membrane ML for photolithography may include a core layer 100, an interface layer 110 on the core layer 100, and a protective layer 120 on the interface layer 110. The interface layer 110 and the protective layer 120 may be disposed on one surface of the core layer 100, and the interface layer 110 may be interposed between the core layer 100 and the protective layer 120. The core layer 100, the interface layer 110, and the protective layer 120 are substantially same as the core layer 100, the interface layers 110a and 110b, and the protective layers 120a and 120b described with reference to FIGS. 1 and 2A to 2D, respectively.

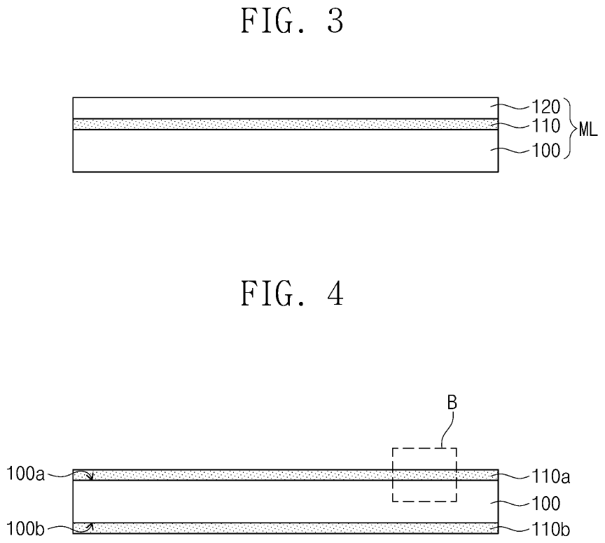

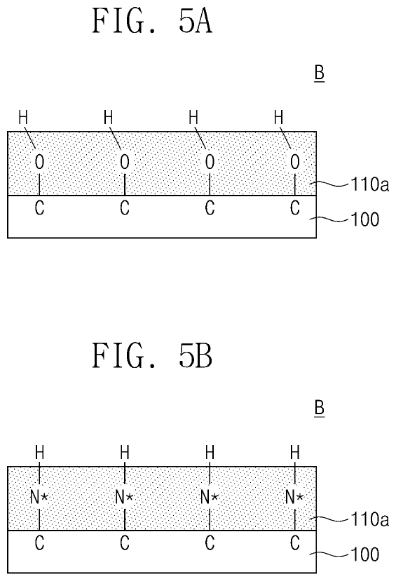

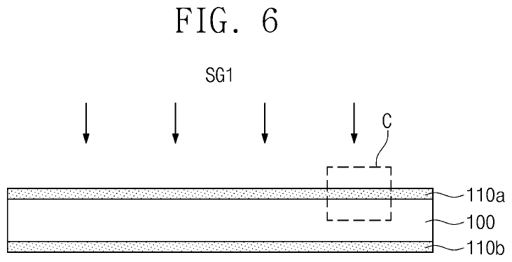

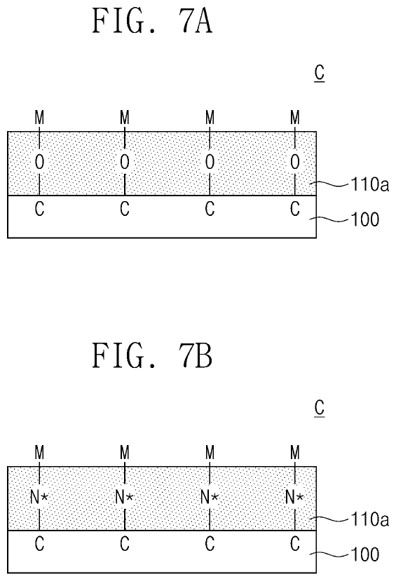

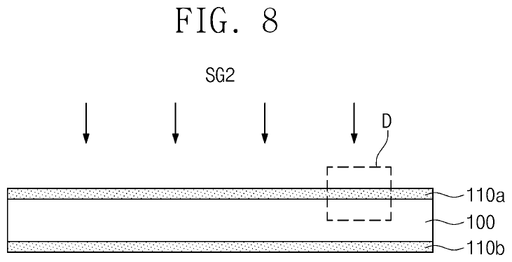

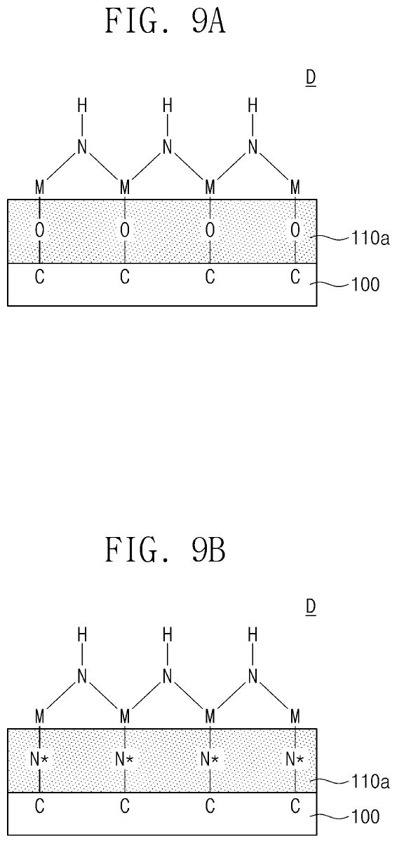

FIGS. 4, 6, and 8 are cross-sectional views illustrating a method of manufacturing a protective membrane for photolithography according to some embodiments of the inventive concept. FIGS. 5A and 5B are enlarged views of portion “B” of FIG. 4. FIGS. 7A and 7B are enlarged views of portion “C” of FIG. 6. FIGS. 9A and 9B are enlarged views of portion “D” of FIG. 8. For simplification of the description, description overlapping with the protective membrane for photolithography described with reference to FIGS. 1 and 2A to 2D will be omitted.

Referring to FIGS. 4, 5A and 5B, a core layer 100 may be provided. The core layer 100 may include carbon (e.g., a carbon-based material, such as a carbon nanomaterial). The core layer 100 may include, for example, at least one of single-layer graphene, multi-layer graphene, carbon nanotubes (CNT), fullerene, nanographite, and graphite.

A plasma treatment process may be performed on the core layer 100, and thus interface layers 110a and 110b may be formed on a surface of the core layer 100. The core layer 100 may have a first surface 100a and a second surface 100b opposite to each other. According to some embodiments, the plasma treatment process may be performed on the first surface 100a and the second surface 100b of the core layer 100, and thus the interface layers 110a and 110b may be formed on the first surface 100a and the second surface 100b of the core layer 100, respectively. According to other embodiments, the plasma treatment process may be performed only on the first surface 100a or the second surface 100b, and in this case, as described with reference to FIG. 3, an interface layer 110 may be formed on only one surface of the core layer 100.

Forming the interface layers 110a and 110b may include forming a reactive group bonded to a carbon of the core layer 100 by performing the plasma treatment process, wherein the reactive group includes oxygen (O) or nitrogen (N). The reactive group may include, for example, at least one of carbonyl (═O), an ether (—O—), a hydroxyl (—OH), an imine or tertiary amine (e.g., C═N— or C₂N—), an imine or secondary amine (e.g., C═NH or C₂NH), and a primary amine (—NH₂). The interface layers 110a and 110b may include, for example, at least one of a C═O bond, a C—O—C bond, a C—OH bond, a C₂N—C bond, a C═N—C bond, a C₂NH bond, a C═NH bond, and a C—NH₂ bond. For example, the interface layers 110a and 110b may be bonded to the core layer 100 through at least one of a C═O bond, a C—O—C bond, a C—OH bond, a C₂N—C bond, a C═N—C bond, a C₂NH bond, a C═NH bond, and a C—NH₂ bond. For example, referring to FIG. 5A, in some embodiments, the reactive group may include an —OH, and the interface layers 110a and 110b (not shown) may be connected to the core layer 100 through a C—OH bond. As another example, referring to FIG. 5B, the reactive group may include at least one of ═NH and —NH₂, and the interface layers 110a and 110b (not shown) may be connected to the core layer 100 through at least one of a C₂NH bond, a C═NH bond, and a C—NH₂ bond. In FIG. 5B, “*” denotes the nitrogen to which the carbon of the core layer 100 and an additional hydrogen (H) are bonded.

In some embodiments, the plasma treatment process may be performed using a reaction gas containing oxygen or nitrogen. The reaction gas may include, for example, at least one of oxygen (O₂), ozone (O₃), nitrogen (N₂), and ammonia (NH₃). In some embodiments, the plasma treatment process may be performed using a mixed gas of the reaction gas and an inert gas (e.g., argon). For example, the plasma treatment process may be performed under vacuum (e.g., at a pressure in a range of about 1×10⁻⁸ Torr to about 1×10² Torr). In some embodiments, one or more of the following parameters may be used in the plasma process: a substrate surface temperature in a range of about 10° C. to about 800° C.; an inert gas flow in a range of 0 sccm to about 100,000 sccm; a reaction gas flow in a range of about 10 sccm to about 10,000 sccm; and a plasma output in a range of about 1 W to about 1000 W; and a time in a range of about 0.1 seconds to about 100 seconds.

Referring to FIGS. 6, 7A, and 7B, an atomic layer deposition process may be performed on the interface layers 110a and 110b in which the reactive groups are formed. Performing the atomic layer deposition process may include providing a first source gas SG1 including an element “M”. The element “M” may include at least one of Ti, B, Ta, Nb, V, Cu, Ga, Ge, Zr, Mo, In, Hf, and W. The element “M” may combine with the oxygen or nitrogen in the reactive group of the interface layers 110a and 110b to form a bond. Accordingly, in some embodiments, at least one of a C—O—M bond, a C₂N—M bond, a C═N—M bond, and a C—NH—M bond may be formed. For example, referring to FIG. 7A, the element “M” may form a bond with an oxygen in a reactive group of the interface layers 110a and 110b (not shown), and a C—O—M bond may be formed. As another example, referring to FIG. 7B, the element “M” may form a bond with a nitrogen of a reactive group in the interface layers 110a and 110b (not shown), and at least one of a C₂N—M bond, a C═N—M bond, and a C—NH—M bond may be formed. In FIG. 7B, “*” denotes a nitrogen to which carbon (C) of the core layer 100 and an additional hydrogen (H) are bonded.

Referring to FIGS. 8, 9A, and 9B, in some embodiments, performing the atomic layer deposition process may further include providing a second source gas SG2 containing nitrogen (N). Nitrogen (N) provided from the second source gas SG2 may be combined with the element “M” to form a nitride. For example, the element “M” may be Ti, the first source gas SG1 may include TiCl₄, and the second source gas SG2 may include ammonia (NH₃). In this case, TiN may be formed by the atomic layer deposition process.

Performing the atomic layer deposition process may include repeating a cycle including providing the first source gas SG1 and providing the second source gas SG2 multiple times. The plasma treatment process described with reference to FIGS. 4, 5A and 5B may be performed before the atomic layer deposition process and between the plurality of cycles of the atomic layer deposition process. The atomic layer deposition process and the plasma processing process may be performed in-situ in one chamber or may be respectively performed in different separate chambers.

Referring back to FIG. 1, the protective layers 120a and 120b may be formed by the atomic layer deposition process. In some embodiments, the protective layers 120a and 120b may include the nitride including the element “M”. For example, the element “M” may be Ti, and the protective layers 120a and 120b may include TiN. The core layer 100, the interface layers 110a and 110b, and the protective layers 120a and 120b may constitute a protective membrane ML for photolithography.

It may be difficult to directly form the protective layers 120a and 120b on the core layer 100 formed of carbon-based material. As such, according to embodiments of the inventive concept, the interface layers 110a and 110b including the reactive group may be formed on the core layer 100, and the protective layers 120a and 120b may be formed on the interface layers 110a and 110b. The element “M” of the protective layers 120a and 120b may be combined to oxygen or nitrogen of the reactive group of the interface layers 110a and 110b. Accordingly, the protective layers 120a and 120b may be formed on the core layer 100 on which the interface layers 110a and 110b are formed.

When the core layer 100 including a carbon-based material is used by itself in an extreme ultraviolet photolithography process, the core layer 100 may lack chemical durability against hydrogen plasma that may be used to clean the apparatus performing the extreme ultraviolet photolithography process. According to embodiments of the inventive concept, the protective layers 120a and 120b may be formed on the core layer 100 on which the interface layers 110a and 110b are formed, and the protective membrane ML including the interface layers 110a and 110b and the protective layers 120a and 120b may be used in an extreme ultraviolet photolithography process. As the protective membrane ML includes the protective layers 120a and 120b, chemical durability against hydrogen plasma may be increased. In addition, the protective membrane ML may include the core layer 100 including carbon, and thus, the protective membrane ML may have excellent mechanical durability and heat dissipation.

Accordingly, a protective membrane for photolithography having excellent heat dissipation and excellent chemical and mechanical durability may be provided.

### COMPARATIVE EXAMPLE 1

A TiN protective layer was directly formed on a core layer including multilayer graphene by performing an atomic layer deposition process. The atomic layer deposition process was performed under an argon atmosphere at a working pressure of 1 Ton and a substrate temperature of 460° C. A TiCl₄ precursor was injected for 1 second at a vapor pressure of 7.6 Ton and purged for 4 seconds. Thereafter, NH₃ reaction gas was injected at 100 sccm for 3 seconds and purged for 3 seconds. The above-described cycle was performed 200 times to form the TiN protective layer.

### COMPARATIVE EXAMPLE 2

A TiN protective layer was directly formed on a core layer including multilayer graphene by performing an atomic layer deposition process. Conditions of the atomic layer deposition process were the same as those of Comparative Example 1, and the cycle described in Comparative Example 1 was performed 400 times to form the TiN protective layer.

### EXAMPLE 1

An interface layer was formed on a core layer including multilayer graphene by performing an oxygen (O₂) plasma treatment process. A reactive group containing oxygen was formed by exposing a surface of the core layer to the oxygen (O₂) plasma for 30 seconds to 120 seconds. Thereafter, an atomic layer deposition process was performed on the interface layer to form a TiN protective layer. Conditions of the atomic layer deposition process were the same as those of Comparative Example 1, and the cycle described in Comparative Example 1 was performed 48 times to form a TiN protective layer.

### Example 2

In the same manner as in Example 1, an oxygen (O₂) plasma treatment process was performed on a core layer including multilayer graphene to form an interface layer. A reactive group containing oxygen was formed by exposing a surface of the core layer to oxygen (O₂) plasma for 30 seconds to 120 seconds. Thereafter, an atomic layer deposition process was performed on the interface layer to form a TiN protective layer. Conditions of the atomic layer deposition process were the same as those of Comparative Example 1, and the cycle described in Comparative Example 1 was performed 72 times to form a TiN protective layer.

### EXAMPLE 3

In the same manner as in Example 1, an oxygen (O₂) plasma treatment process was performed on a core layer including multilayer graphene to form an interface layer. A reactive group containing oxygen was formed by exposing a surface of the core layer to oxygen (O₂) plasma for 30 seconds to 120 seconds. Thereafter, an atomic layer deposition process was performed on the interface layer to form a TiN protective layer. Conditions of the atomic layer deposition process were the same as those of Comparative Example 1, and the cycle described in Comparative Example 1 was performed 200 times to form a TiN protective layer.

### EXAMPLE 4

An interface layer was formed on a core layer including multilayer graphene by performing an ammonia (NH₃) plasma treatment process. A reactive group containing nitrogen was formed by exposing a surface of the core layer to ammonia (NH₃) plasma for 25 to 100 seconds. Thereafter, an atomic layer deposition process was performed on the interface layer to form a TiN protective layer. Conditions of the atomic layer deposition process were the same as those of Comparative Example 1, and the cycle described in Comparative Example 1 was performed 48 times to form a TiN protective layer.

### EXAMPLE 5

In the same manner as in Example 4, an ammonia (NH₃) plasma treatment process was performed on a core layer including multilayer graphene to form an interface layer. A reactive group containing nitrogen was formed by exposing a surface of the core layer to ammonia (NH₃) plasma for 25 to 100 seconds. Thereafter, an atomic layer deposition process was performed on the interface layer to form a TiN protective layer. Conditions of the atomic layer deposition process were the same as those of Comparative Example 1, and the cycle described in Comparative Example 1 was performed 72 times to form a TiN protective layer.

### EXAMPLE 6

In the same manner as in Example 4, an ammonia (NH₃) plasma treatment process was performed on a core layer including multilayer graphene to form an interface layer. A reactive group containing nitrogen was formed by exposing a surface of the core layer to ammonia (NH₃) plasma for 25 to 100 seconds. Thereafter, an atomic layer deposition process was performed on the interface layer to form a TiN protective layer. Conditions of the atomic layer deposition process were the same as those of Comparative Example 1, and the cycle described in Comparative Example 1 was performed 200 times to form a TiN protective layer.

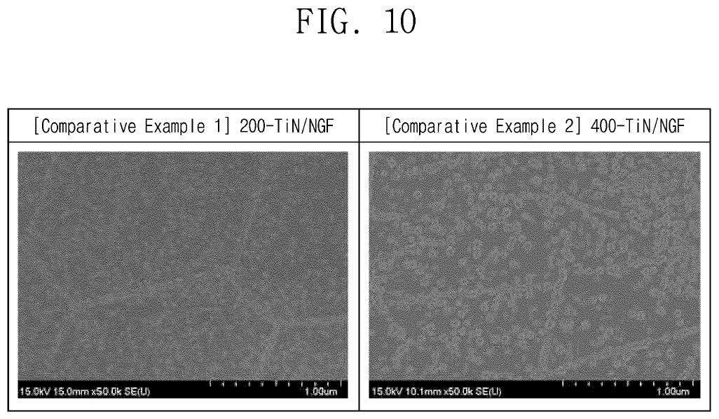

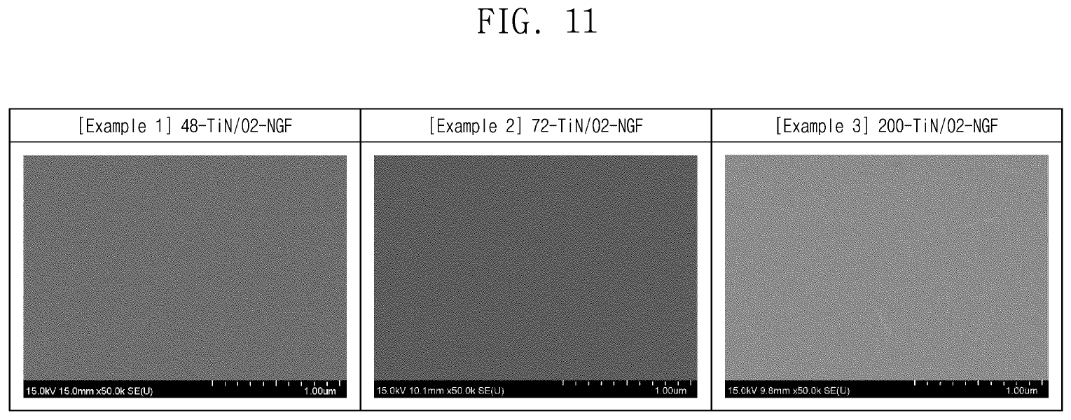

FIG. 10 provides SEM images of protective membranes for photolithography according to Comparative Examples 1 and 2, FIG. 11 provides SEM images of protective membranes for photolithography according to Examples 1-3 of the inventive concept.

Referring to FIG. 10, when the TiN protective layer is directly formed on the core layer on which an interface layer is not formed, it may be confirmed that the TiN protective layer does not continuously grow in a planar direction (e.g., a direction parallel to the first surface 100a of the core layer 100 in FIG. 1).

Referring to FIG. 11, when the interface layer is formed on the core layer by performing the plasma treatment process and the TiN protective layer is formed on the interface layer, it may be confirmed that the TiN protective layer is continuously grown in a planar direction (e.g., a direction parallel to the first surface 100a of the core layer 100 in FIG. 1).

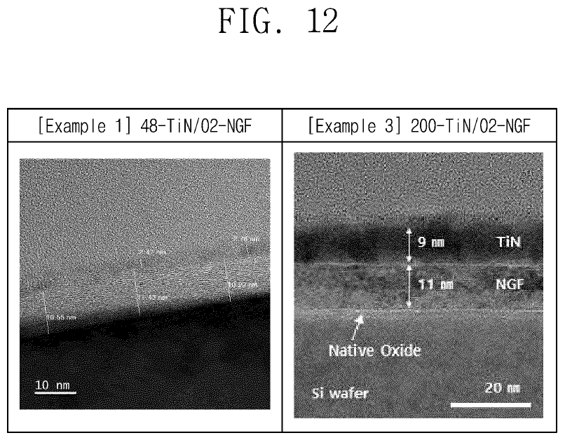

FIGS. 12 and 13 are TEM images illustrating the cross-section of protective membranes for photolithography according to embodiments of the inventive concept.

Referring to FIG. 12, it may be confirmed that each of the TiN protective layers according to Examples 1 and 3 is continuously grown to have a thickness of about 2 nm to 9 nm on one surface of the core layer including the multilayer graphene.

Referring to FIG. 13, it may be confirmed that each of the TiN protective layers according to Examples 4 to 6 is continuously grown to have a thickness of about 2 nm to 11 nm on one surface of the core layer including the multilayer graphene.

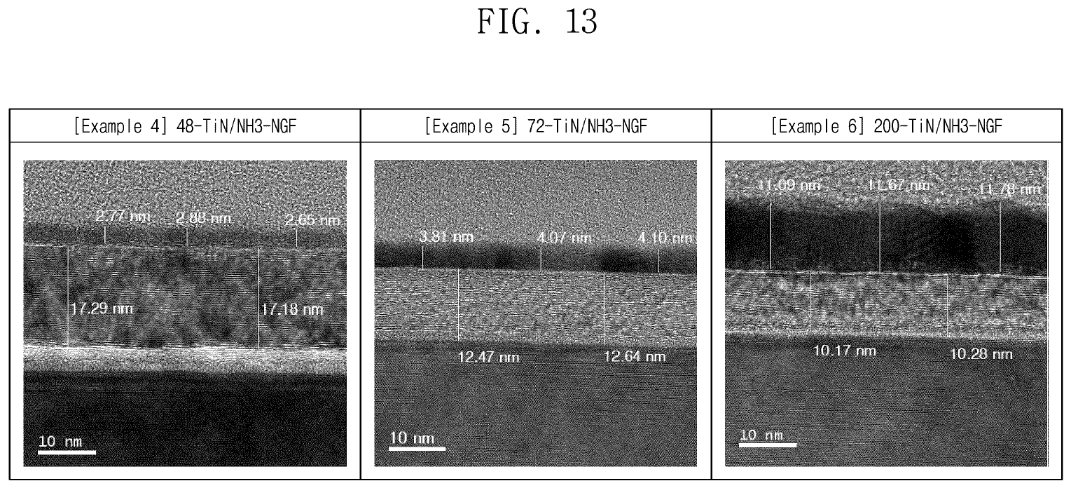

FIG. 14 is a graph quantitatively illustrating a Ti content with respect to a thickness of a TiN protective layer in a protective membrane for photolithography according to embodiments of the inventive concept.

Referring to FIG. 14, in the TiN protective layers (TiN on O₂-NGF) according to Examples 1 to 3 and the TiN protective layers (TiN on NH₃-NGF) according to Examples 4 to 6, it may be confirmed that the Ti content (atomic %) is proportional to a thickness of the TiN protective layer. Accordingly, it may be confirmed that, when the thickness of the TiN protective layer is relatively thin, the thickness of the TiN protective layer is capable of being inferred through the Ti content (atomic %) in the TiN protective layer.

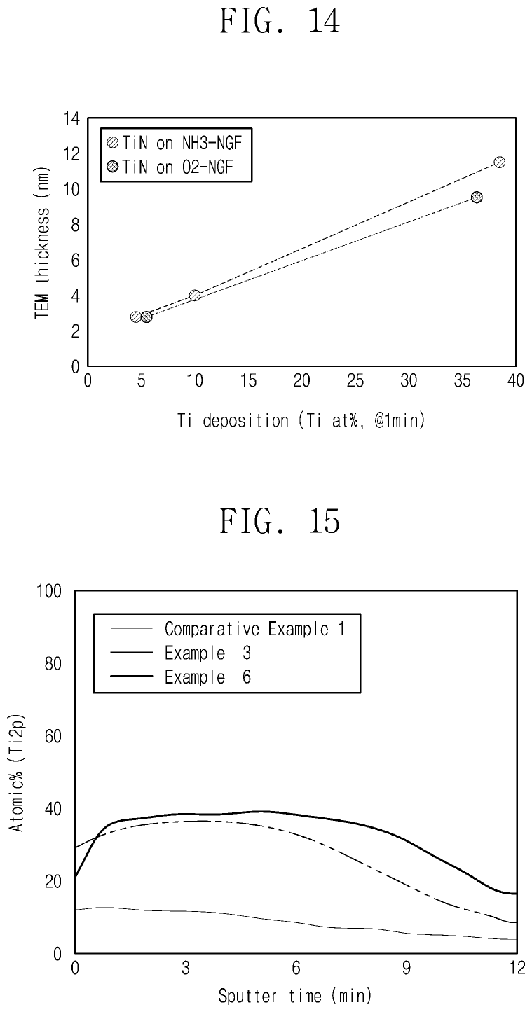

FIG. 15 is a graph illustrating growth by atomic layer deposition of protective membranes for photolithography according to embodiments of the inventive concept and Comparative Example 1.

FIG. 15 shows the Ti content (at %) of each of the TiN protective layers formed according to Comparative Example 1 and Examples 3 and 6. When forming the TiN protective layer on the interface layer formed by the oxygen (O₂) or ammonia (NH₃) plasma treatment process according to Example 3 or Example 6, it may be confirmed that the Ti content (at %) of the TiN protective layer is relatively high compared to the case of directly forming the TiN protective layer on the core layer including multilayer graphene according to Comparative Example 1. That is, when the interface layer is formed on the core layer including multilayer graphene by performing the oxygen (O₂) or ammonia (NH₃) plasma treatment process, the TiN protective layer may be easily formed on the interface layer by the atomic layer deposition process.

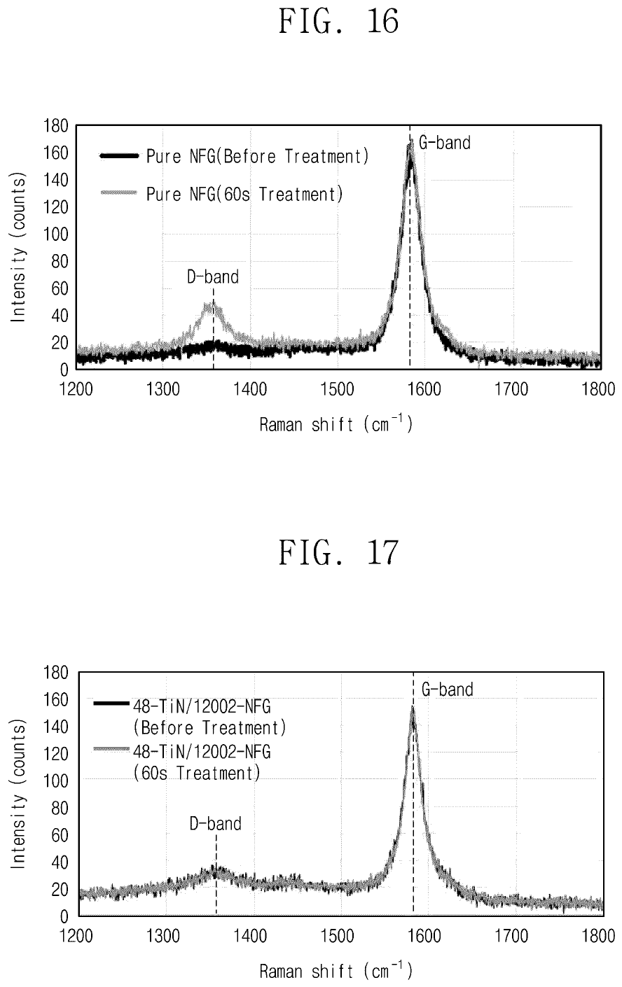

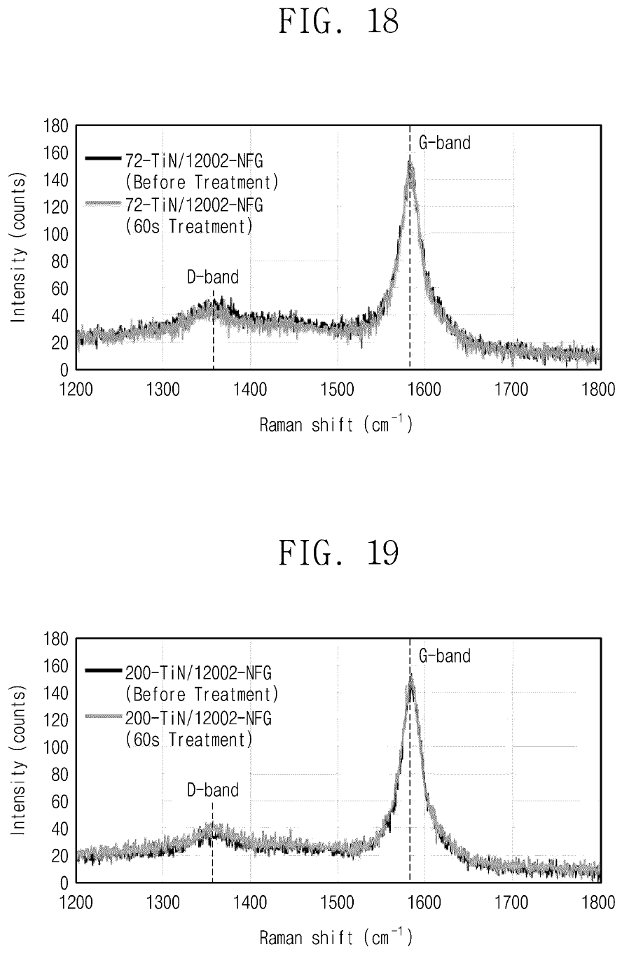

FIG. 16 is a graph illustrating Raman spectra of a core layer including multilayer graphene before and after being exposed to hydrogen plasma. FIGS. 17 to 19 are graphs illustrating Raman spectra of protective membranes formed according to Examples 1, 2, and 3 respectively before and after being exposed to hydrogen plasma.

Referring to FIG. 16, a Raman spectrum before the core layer including multilayer graphene was exposed to hydrogen plasma was compared with a Raman spectrum after 100 W hydrogen plasma was treated on the core layer for 60 seconds. Referring to FIGS. 17 to 19,

Raman spectra before the protective membranes formed according to Examples 1, 2 and 3 were exposed to hydrogen plasma were compared with Raman spectra after 100 W hydrogen plasma treatment were treated on the protective membranes for 60 seconds. As a ratio (ID/IG) of a signal sensitivity (ID) of a defect (D) band near 1350 cm⁻¹ with respect to a signal sensitivity (IG) of a graphitic (G) band near 1580 cm⁻¹ is close to 0, it means that there is negligible or no defect.

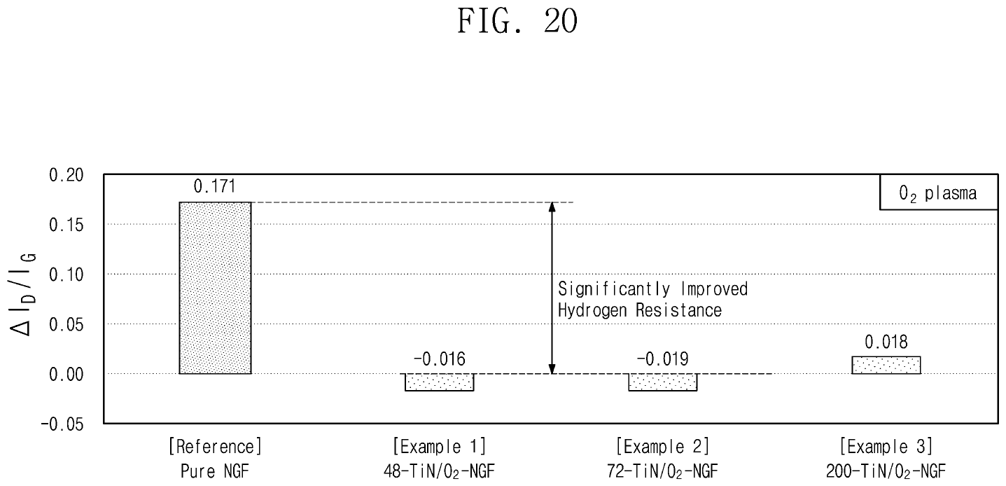

FIG. 20 is a graph illustrating a change in the ratio of signal sensitivity obtained from Raman spectra of FIGS. 16 to 19.

Referring to FIG. 20, the change (ΔID/IG) in the signal sensitivity ratio before and after the core layer including multilayer graphene was exposed to hydrogen plasma was about 0.171. It was determined that the change (ΔID/IG) in the signal sensitivity ratio before and after the protective membranes formed according to Examples 1 to 3 are exposed to hydrogen plasma was close to zero. That is, the protective membranes formed according to Examples 1 to 3 may have increased durability against hydrogen plasma relative to the core layer alone.

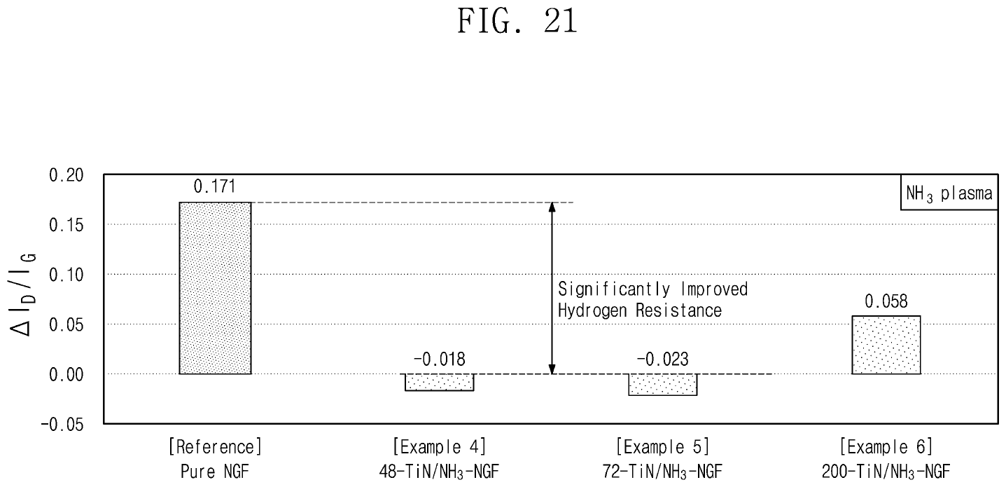

FIG. 21 is a graph illustrating the change in the ratio of signal sensitivity before and after protective membranes formed according to Examples 4 to 6 are exposed to hydrogen plasma.

First, as described with reference to FIG. 16, the Raman spectrum before the core layer including multilayer graphene was exposed to hydrogen plasma was compared with the Raman spectrum after a 100 W hydrogen plasma treatment was performed on the core layer for 60 seconds. As a result, the change (ΔID/IG) in the signal sensitivity ratio before and after the core layer including multilayer graphene was exposed to hydrogen plasma was obtained.

The Raman spectra before the protective membranes formed according to Examples 4, 5, and 6 were exposed to hydrogen plasma were compared with the Raman spectra after the protective membranes were treated with 100 W hydrogen plasma for 60 seconds. As a result, the change (ΔID/IG) in the ratio of signal sensitivity before and after the protective membranes formed according to Examples 4 to 6 were exposed to hydrogen plasma was obtained.

The change (ΔID/IG) in the signal sensitivity ratio before and after the core layer including multilayer graphene was exposed to hydrogen plasma was about 0.171. It was determined that the change (ΔID/IG) in the ratio of signal sensitivity before and after the protective membranes formed according to Examples 4 to 6 are exposed to hydrogen plasma is close to zero. That is, the protective membranes formed according to Examples 4 to 6 may have increased durability against hydrogen plasma.

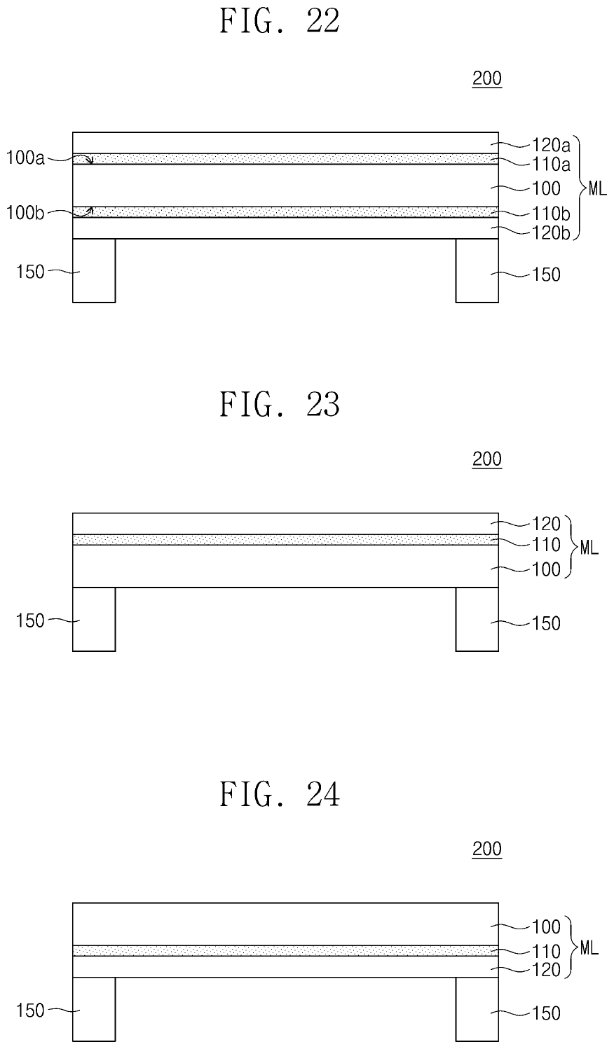

FIGS. 22 to 24 are cross-sectional views of a pellicle including a protective membrane for photolithography according to embodiments of the inventive concept.

Referring to FIGS. 22 to 24, a photomask pellicle 200 may include a protective membrane ML described with reference to FIGS. 1 to 3. The protective membrane ML may be referred to as a pellicle membrane. The pellicle 200 for a photomask may further include a pellicle frame 150 for supporting the pellicle membrane ML. The pellicle frame 150 may serve to separate the pellicle membrane ML from the photomask by a certain distance. In some embodiments, the pellicle frame 150 may be disposed at an edge of the pellicle membrane ML.

For example, as shown in FIG. 22, the pellicle membrane ML may include a first protective layer 120a and a second protective layer 120b formed on a first surface 100a and a second surface 100b of a core layer 100, respectively, and the second protective layer 120b (or the first protective layer 120a) may be interposed between the core layer 100 and the pellicle frame 150. As another example, as shown in FIG. 23, a pellicle membrane ML may include a protective layer 120 formed on one surface of a core layer 100, and the core layer 100 may be interposed between the protective layer 120 and the pellicle frame 150. As another example, as shown in FIG. 24, a pellicle membrane ML may include a protective layer 120 formed on one surface of a core layer 100, and the protective layer 120 may be interposed between the core layer 100 and the pellicle frame 150.

In some embodiments, the photomask pellicle 200 may be used in an extreme ultraviolet exposure process.

According to embodiments of the inventive concept, the pellicle membrane ML may include the core layer 100 including a carbon (e.g, a carbon-based material), and thus, the pellicle membrane ML may have excellent mechanical durability and heat dissipation. In addition, the pellicle membrane ML may include the protective layers 120, 120a, and 120b formed on the core layer 100, and accordingly, the pellicle membrane ML may have desirable chemical durability against hydrogen plasma that may be used for cleaning an apparatus performing the extreme ultraviolet exposure process.

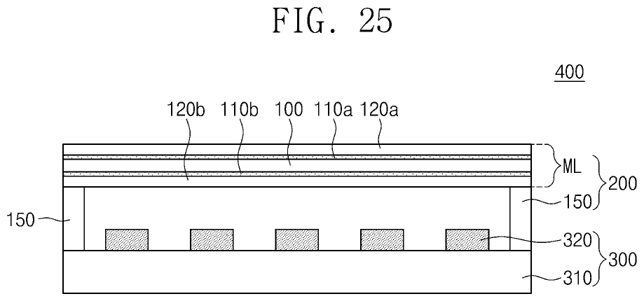

FIG. 25 is a cross-sectional view of a reticle including a pellicle for a photo mask according to embodiments of the inventive concept.

Referring to FIG. 25, a reticle 400 may include a photomask 300 and a pellicle 200 for protecting the photomask 300. The photomask 300 may include a mask substrate 310 and mask patterns 320 on the mask substrate 310. The pellicle 200 may include a pellicle membrane ML provided to be spaced apart from the mask patterns 320, and a pellicle frame 150 supporting the pellicle membrane ML. The pellicle frame 150 may be disposed at an edge of the mask substrate 310 and may support the pellicle membrane ML such that the pellicle membrane ML is spaced apart from the mask patterns 320. The pellicle membrane ML may be substantially the same as the protective membrane ML described with reference to FIGS. 1 to 3.

The reticle 400 may be used in an extreme ultraviolet exposure process. During the EUV exposure process, EUV light may pass through the pellicle membrane ML and be provided onto the photomask 300. The pellicle 200 may protect the photomask 300 from external contaminants during the extreme ultraviolet exposure process.

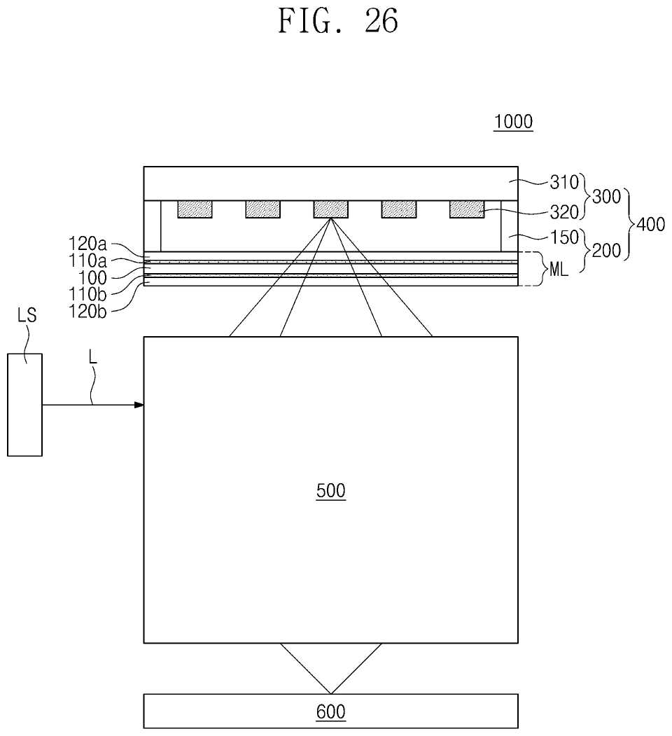

FIG. 26 is a conceptual diagram of an exposure apparatus for lithography using a reticle including a pellicle according to embodiments of the inventive concept.

Referring to FIG. 26, an exposure apparatus 1000 for lithography may include a light source LS, a reticle 400, and an optics 500. Light “L” generated from the light source LS may be irradiated to a substrate 600 through the reticle 400. The light “L” may be, for example, extreme ultraviolet light. The reticle 400 may be substantially the same as the reticle 400 described with reference to FIG. 25. The reticle 400 may be, for example, a reflective reticle. The optics 500 may be disposed between the reticle 400 and the substrate 600 and may include an illumination optical system and a projection optical system. The light “L” may be irradiated to the reticle 400 through the optics 500, and the light “L” reflected from the reticle 400 may be incident on the substrate 600 through the optics 500.

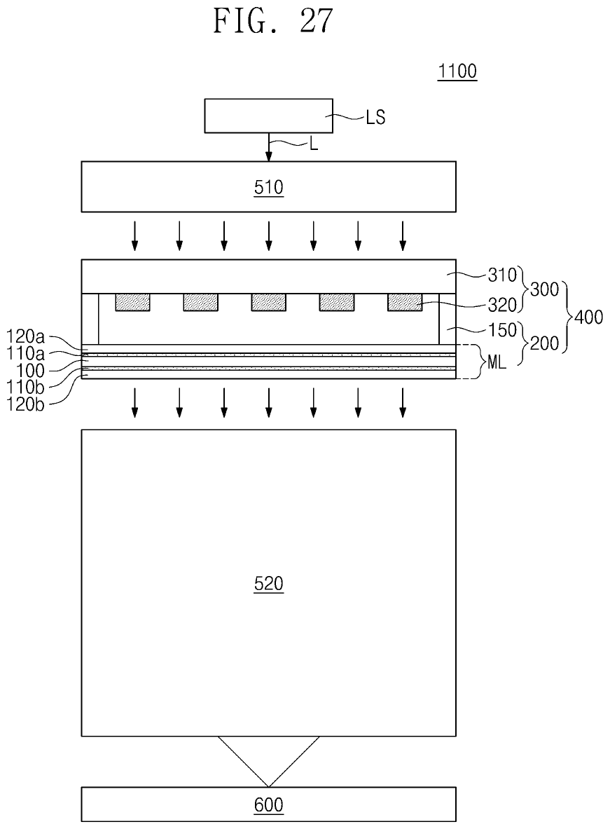

FIG. 27 is a conceptual diagram of an exposure apparatus for lithography using a reticle including a pellicle according to embodiments of the inventive concept.

Referring to FIG. 27, an exposure apparatus 1100 for lithography may include a light source LS, a reticle 400, a first optics 510, and a second optics 520. Light “L” generated from the light source LS may be irradiated to a substrate 600 through the reticle 400. The light “L” may be, for example, extreme ultraviolet light. The reticle 400 may be substantially the same as the reticle 400 described with reference to FIG. 25. The reticle 400 may be, for example, a transmissive reticle. The first optics 510 may be disposed between the light source LS and the reticle 400 and may include an illumination optical system. The second optics 520 may be disposed between the reticle 400 and the substrate 600 and may include a projection optical system. The light “L” may be irradiated to the reticle 400 through the first optics 510 and may pass through the reticle 400. The light “L” passing through the reticle 400 may be incident on the substrate 600 through the second optics 520.

According to the aspect of the inventive concept, the protective membrane for photolithography may include the core layer including carbon, the interface layer including a reactive group bonded to a carbon of the core layer and the protective layer on the interface layer. The reactive group may include oxygen or nitrogen bonded to carbon of the core layer, and the element “M” of the protective layer may be bonded to the oxygen or the nitrogen of the reactive group of the interface layer. Accordingly, the protective layer may be easily formed on the core layer on which the interface layer is formed.

The protective membrane may include the core layer including carbon, and thus the protective membrane may have excellent mechanical durability and heat dissipation. In addition, the protective membrane may include the protective layer, and thus the chemical durability of the protective membrane against the hydrogen plasma may be increased.

Accordingly, a protective membrane for photolithography having desirable heat dissipation and excellent chemical and mechanical durability may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

1. A protective membrane for photolithography comprising:
a core layer including carbon;
an interface layer on the core layer; and
a protective layer on the interface layer,
wherein the interface layer includes a reactive group bonded to a carbon atom of the core layer,
wherein the reactive group includes an oxygen atom or a nitrogen atom, and
wherein the protective layer includes an element “M”, and the element “M” is bonded to the oxygen atom or the nitrogen atom of the reactive group.

2. The protective membrane for the photolithography of claim 1, wherein the interface layer is bonded to the core layer and the protective layer with at least one of a C—O—M bond, a C═N—M bond, a C₂═N—M bond, and a C—NH—M bond.

3. The protective membrane for the photolithography of claim 1, wherein the reactive group includes at least one of a carbonyl, an ether, a hydroxyl, an imine, a primary amine, a secondary amine, and a tertiary amine.

4. The protective membrane for the photolithography of claim 1, wherein the core layer includes at least one of single-layer graphene, multi-layered graphene, carbon nanotubes (CNT), a fullerene, nanographite, and graphite.

5. The protective membrane for the photolithography of claim 1, wherein the protective layer includes a nitride containing the element “M”.

6. The protective membrane for the photolithography of claim 1, wherein the element “M” of the protective layer includes at least one of Ti, B, Ta, Nb, V, Cu, Ga, Ge, Zr, Mo, In, Hf and W.

7. The protective membrane for the photolithography of claim 1, wherein a thickness of the core layer is in a range of about 0.1 nm to about 50 nm.

8. The protective membrane for the photolithography of claim 1, wherein the core layer has a first surface and a second surface opposite to each other,
wherein a first interface layer is on the first surface of the core layer, and a second interface layer is on the second surface of the core layer, and
wherein a first protective layer is on the first interface layer and a second protective layer is on the second interface layer.

9. The protective membrane for the photolithography of claim 8, wherein the first interface layer includes a first reactive group, and the second interface layer includes a second reactive group, and
wherein the first reactive group and the second reactive group are the same as or different from each other.

10. The protective membrane for the photolithography of claim 9, wherein each of the first protective layer and the second protective layer includes the element “M”,
wherein the first interface layer bonds to the core layer and the first protective layer to form at least one of a C—O—M bond, a C═N—M bond, a C₂═N—M bond, and a C—NH—M bond, and
wherein the second interface layer bonds to the core layer and the second protective layer to form at least one of a C—O—M bond, a C═N—M bond, a C₂═N—M bond, and a C—NH—M bond.

11. The protective membrane for the photolithography of claim 1, wherein a thickness of the protective layer is in a range of about 0.5 nm to about 10 nm.

12. The protective membrane for the photolithography of claim 1, wherein an extreme ultraviolet transmittance of the protective membrane is about 80% or more, and an extreme ultraviolet reflectance of the protective membrane is about 0.04% or less.

13. The protective membrane for the photolithography of claim 1, wherein the protective membrane is configured for use in at least one of an optical filter, a dynamic gas lock filter, an optical protector, and a pellicle.

14. A pellicle for a photo mask comprising:
a pellicle membrane; and
a pellicle frame supporting the pellicle membrane,
wherein the pellicle membrane includes:
a core layer including carbon;
an interface layer on the core layer; and
a protective layer on the interface layer,
wherein the interface layer includes a reactive group bonded to a carbon atom of the core layer, and the reactive group includes an oxygen atom or a nitrogen atom, and
wherein the protective layer includes an element “M” and the element “M” is bonded to the oxygen atom or the nitrogen atom of the reactive group.

15. The pellicle for the photo mask of claim 14, wherein the reactive group includes at least one of a carbonyl, an ether, a hydroxyl, an imine, a primary amine, a secondary amine, and a tertiary amine.

16. The pellicle for the photo mask of claim 14, wherein the interface layer bonds to the core layer and the protective layer with at least one of a C—O—M bond, a C═N—M bond, a C₂═N—M bond, and a C-NH-M bond.

17. The pellicle for the photo mask of claim 16, wherein the element “M” of the protective layer includes at least one of Ti, B, Ta, Nb, V, Cu, Ga, Ge, Zr, Mo, In, Hf and W.

18. The pellicle for the photo mask of claim 17, wherein the protective layer includes a nitride containing the element “M”.

19. The pellicle for the photo mask of claim 14, wherein the core layer includes at least one of single layer graphene, multilayer graphene, carbon nanotubes (CNT), fullerene, nanographite, and graphite.

20. The pellicle for the photo mask of claim 14, wherein the pellicle is configured for use in an extreme ultraviolet exposure process.

21-25. (canceled)
